(19) United States
(12) Patent Application Publication
(10) Pub. No.: US 2024/0063094 A1
(43) Pub. Date: Feb. 22, 2024

(54) SEMICONDUCTOR DEVICE ASSEMBLIES WITH A CAVITY EXPOSING THROUGH-SILICON VIAS FOR CONTROLLER ATTACHMENT

(71) Applicant: Micron Technology, Inc., Boise, ID (US)

(72) Inventors: Terrence B. McDaniel, Boise, ID (US); Kunal R. Parekh, Boise, ID (US); Wei Zhou, Boise, ID (US)

(21) Appl. No.: 17/892,034

(22) Filed: Aug. 19, 2022

(51) Int. Cl. H01L 23/48; H01L 25/065; H01L 23/00; H01L 23/13; H01L 21/768

(52) U.S. Cl. CPC H01L 23/481; H01L 25/0657; H01L 24/16; H01L 24/32; H01L 24/73; H01L 23/13; H01L 21/76898; H01L 2225/06513; H01L 2225/06517; H01L 2225/06524; H01L 2225/06544; H01L 2225/06589; H01L 2224/73204; H01L 2224/16148; H01L 2224/16227; H01L 2224/16238; H01L 2224/32145; H01L 2224/32225; H01L 21/308

(57) ABSTRACT

A semiconductor device includes a semiconductor substrate including a cavity and a peripheral region surrounding the cavity. The peripheral region includes a first surface and a second surface opposite the first surface. The cavity extends from the first surface partially through the semiconductor substrate to a third surface. The third surface is parallel to the first surface and is located between the first surface and the second surface. The semiconductor device also includes a plurality of through-silicon vias (TSVs) extending between the first surface and the third surface.

### TECHNICAL FIELD

The present disclosure generally relates to semiconductor device assemblies, and more particularly relates to semiconductor device assemblies with cavity exposing through-silicon vias for device attachment.

### BACKGROUND

Through silicon vias (TSVs) are a technology for connecting various semiconductor dies in a stacked configuration. TSVs are vertical electrical connections that extend completely through a silicon wafer or die. TSVs can be used as high-performance interconnections in semiconductor device assemblies to create three-dimensional packages and three-dimensional integrated circuits. As TSVs allow electrical signals to pass through the substrates, they enable the packaging with smaller device sizes with reduced signal paths.

### BRIEF DESCRIPTION OF THE DRAWINGS

FIG. 1 is a simplified schematic cross-sectional view of a semiconductor device in accordance with embodiments of the present technology.

FIGS. 2A-2G are simplified schematic cross-sectional views illustrating a series of fabrication steps of semiconductor device assemblies in accordance with an embodiment of the present technology.

FIG. 3 is a simplified schematic cross-sectional view of a semiconductor device assembly in accordance with embodiments of the present technology.

FIG. 4 is a schematic view showing a system that includes a semiconductor device assembly configured in accordance with an embodiment of the present technology.

FIG. 5 is a flow chart illustrating a method of making a semiconductor device assembly in accordance with an embodiment of the present technology.

### DETAILED DESCRIPTION

As discussed in greater detail below, the technology disclosed herein relates to semiconductor devices and semiconductor device assemblies including TSVs. In particular, the technology discloses a semiconductor device including a semiconductor substrate having a cavity that extends partially through the semiconductor substrate. The semiconductor device includes TSVs that are exposed at the bottom surface of the cavity. The cavity is configured to hold a logic device that can be electrically coupled to the exposed TSVs at the bottom surface of the cavity. The semiconductor device can be configured to be coupled to a stack of TSV devices in a semiconductor device assembly.

Semiconductor devices can include TSVs so that a stack of semiconductor devices in an assembly can be vertically coupled to one another and to additional semiconductor devices, such as logic devices. The stack of semiconductor device can be carried by a packaging substrate, and the additional devices can be positioned, for example, on an outer surface of the packaging substrate and be electrically coupled to the stack of semiconductor devices through conductive structures in the substrate. In such configurations, however, the additional semiconductor devices on the bottom of the stack or near the bottom of the stack may not be ideally positioned. For example, when the additional semiconductor devices are heat-generating elements that require an efficient thermal coupling to a heat sink, the distance between the additional semiconductor devices and a heat sink located on the top of the stack may cause inefficiency and inconvenience in cooling of the additional semiconductor device. Accordingly, improvements in the configuration of semiconductor device assemblies are desirable.

To address these limitations and others, embodiments of the present disclosure provide a semiconductor device assembly including a package substrate, a stack of semiconductor devices, and a top semiconductor device. The stack of semiconductor devices is coupled with the package substrate (e.g., the package substrate is positioned at the bottom of the semiconductor device assembly). Each semiconductor device in the stack includes a plurality of TSVs. The top semiconductor device includes a semiconductor substrate that includes a cavity and a peripheral region that surrounds the cavity. The peripheral region includes a first surface (e.g., a top surface of the top semiconductor device) and a second surface (e.g., a bottom surface of the top semiconductor device). The cavity extends from the first surface partially through the semiconductor substrate to a third surface between the first surface and the second surface (e.g., a bottom surface of the cavity). The third surface is parallel to the first surface. The top semiconductor device also includes a plurality of TSVs. The plurality of the TSVs of the top semiconductor device extends between the first surface and the third surface. The plurality of TSVs of the top semiconductor device is exposed at the third surface. The disclosed semiconductor further includes an additional semiconductor device (e.g., a logic device) positioned within the cavity of the semiconductor substrate. The additional semiconductor device is electrically coupled to the plurality of TSVs of the top semiconductor device at the third surface. The semiconductor device assembly further includes a thermally conductive heat sink. The thermally conductive heat sink can be a heat sink lid for the semiconductor device assembly so that the thermally conductive heat sink is coupled with the first surface of the top semiconductor device and the top surface of the additional semiconductor device.

The disclosed technology provides for semiconductor device assemblies including a TSVs stack where an additional semiconductor device can be positioned within a cavity of a top die of the TSVs. In such a configuration, the additional semiconductor device is positioned near or adjacent to a thermally conductive heat sink. The present technology avoids the issues arising from conventional configurations where the additional semiconductor device is positioned on an opposite side of the TSV stack than the heat sink and thereby required to conduct heat through the TSV stack.

### B. Selected Embodiments of Semiconductor Devices and Semiconductor Device Assemblies, and Associated Methods

Several embodiments of the present technology are described below with reference to processes for forming through vias and conductive routing layers in semiconductor substrates. Many details of certain embodiments are described below with reference to semiconductor dies. The term “semiconductor substrate” is used throughout to include a variety of articles of manufacture, including, for example, individual integrated circuit dies, imager dies, sensor dies, and/or dies having other semiconductor features.

Several of the processes described below may be used to form through vias in an individual die or in a plurality of dies, on a wafer or portion of a wafer. The wafer or wafer portion (e.g., wafer form) can include an unsingulated wafer or wafer portion, or a repopulated carrier wafer. The repopulated carrier wafer can include an adhesive material (e.g., a flexible adhesive) surrounded by a generally rigid frame having a perimeter shape that is comparable to that of an unsingulated wafer and can include singulated elements (e.g., dies) surrounded by the adhesive.

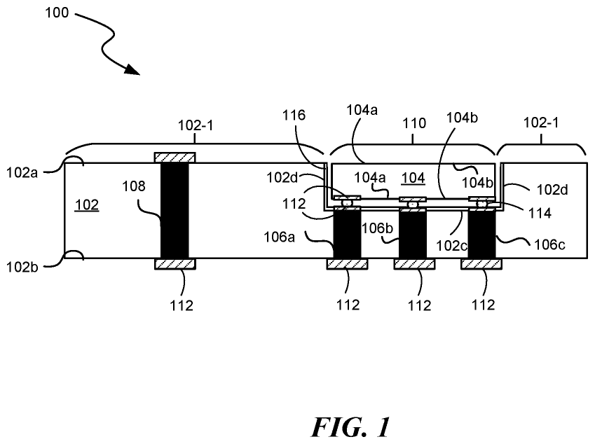

Many specific details of certain embodiments are set forth in FIGS. 1-3 and the following text to provide a thorough understanding of these embodiments. Several other embodiments can have configurations, components, and/or processes different from those described below. A person skilled in the relevant art, therefore, will appreciate that additional embodiments may be practiced without several of the details of the embodiments shown in FIGS. 1-3.

FIG. 1 is a simplified schematic cross-sectional view of a semiconductor device 100 in accordance with embodiments of the present technology. The semiconductor device 100 includes a semiconductor substrate 102 (e.g., a silicon wafer). The semiconductor substrate includes a first surface 102a (e.g., a back surface or a top surface) and a second surface 102b (e.g., an active surface or a bottom surface). The surfaces 102a and 102b are parallel to each other and on opposite sides of the semiconductor substrate 102. The semiconductor substrate 102 includes a cavity 110 which extends from the first surface 102a partially through the semiconductor substrate 102 toward the second surface 102b. For example, the semiconductor substrate 102 can be between about 1.0 and 10,000 μm thick, and the cavity 110 can extend into the semiconductor substrate 102 to a depth that leaves a remaining thickness of semiconductor material of between about 1.0 and 1,000 μm. The semiconductor substrate 102 thereby defines a third surface 102c corresponding to the bottom surface of the cavity 110 and fourth surfaces 102d corresponding to the vertical side surfaces of the cavity 110. The cavity 110 can have a width (e.g., a distance between the fourth surfaces 102d) between about 100 and 100,000 μm and a depth (e.g., a distance between the third surface 102c and a plane defined by the first surface 102a) between about 1.0 and 1,000 μm. The third surface 102c is positioned between the first surface 102a (e.g., a plane defined by the first surface 102a) and the second surface 102b (e.g., a plane defined by the second surface 102b). The third surface 102c is parallel to the first surface 102a and the second surface 102b while the fourth surfaces 102d are perpendicular to the first surface 102a and the second surface 102b.

The cavity 110 is surrounded by a peripheral region 102-1 of the semiconductor substrate 102. In some embodiments, the cavity 110 has a cubic or other rectangular cuboid shape. For example, the cavity 110 has a bottom surface having a rectangular shape and four side surfaces that extend from the edges of the rectangular bottom shape thereby forming a rectangular cuboid cavity. In some embodiments, the cavity 110 has a cylindrical shape (e.g., a cylinder shape).

The semiconductor device 100 can further include through silicon vias (TSVs) (e.g., TSVs 106a, 106b, and 106c collectively referred to as ‘TSVs 106’). A TSV refers to a vertical interconnect that extends at least partially through a semiconductor substrate. Here, the TSVs 106 extend fully through the semiconductor substrate 102 between the second surface 102b and the third surface 102c (e.g., the bottom of the cavity 110). The TSVs have longitudinal shapes having a center axis that is perpendicular to the second surface 102b and the third surface 102c. The TSVs 106 can have, for example, cylindrical shapes having a circular or elliptical top surfaces exposed at the third surface 102c. The TSVs 106 can have diameters between about 0.1 and 100 μm.

The TSVs can be made of a conducting material such as copper, aluminum, gold, and/or other suitable conductive materials or alloys thereof. The TSVs 106 are exposed at the third surface 102c as well as at the second surface 102b. The semiconductor device 100 can also include one or more TSVs (e.g., a TSV 108) extending between the first surface 102a and the second surface 102b in the peripheral regions 102-1 of the semiconductor substrate 102. In some examples, the TSVs 106 and 108 can be electrically active (e.g., coupled to circuit elements), thermally conducting (e.g., configured to transport heat vertically), both, or some combination thereof.

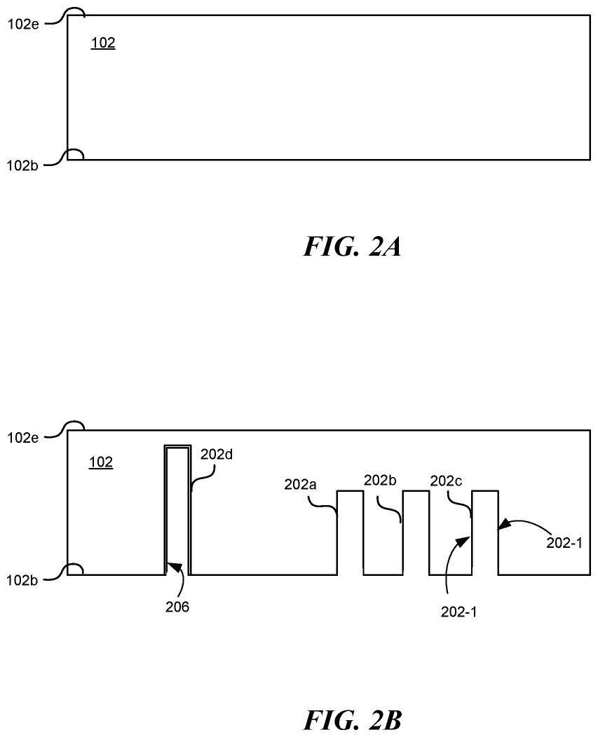

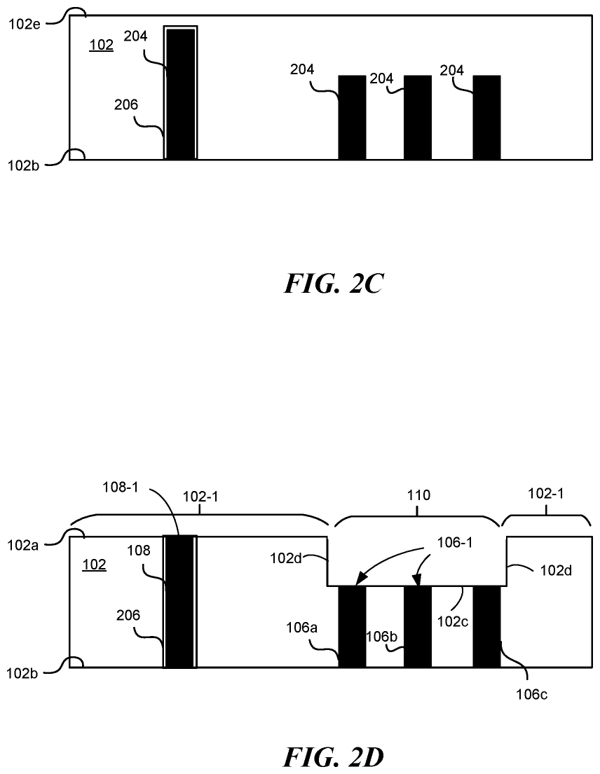

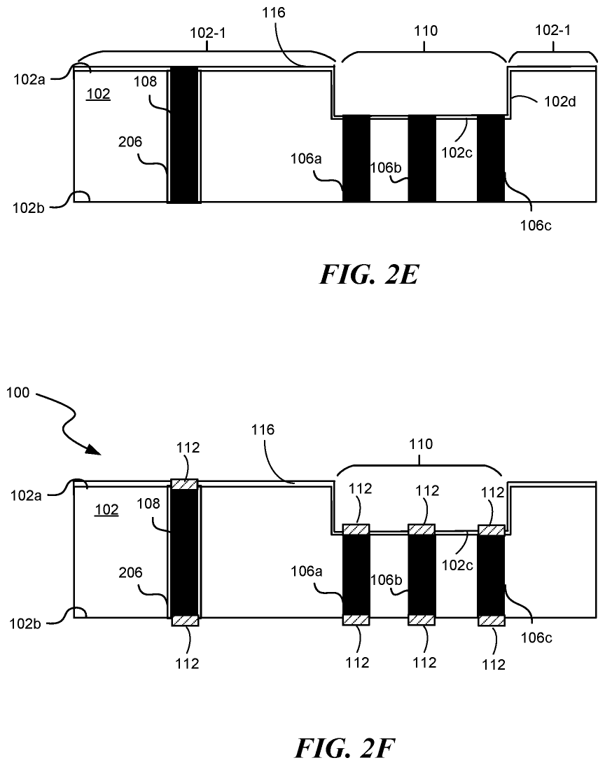

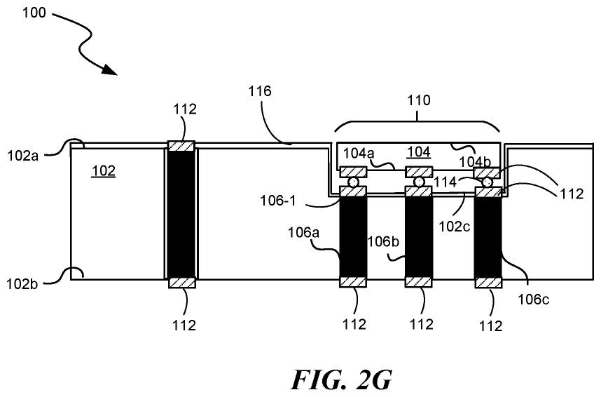

In some embodiments, the semiconductor device 100 includes a passivation layer extending across the third surface 102c and the fourth surfaces 102d of the semiconductor substrate 102 (e.g., the passivation layer 116). The passivation layer 116 can also extend across the first surface 102a (e.g., in the peripheral regions 102-1 of the semiconductor substrate 102 as illustrated in FIGS. 2E-2G). The passivation layer 116 can include silicon dioxide, silicon nitride, other dielectrics, aluminum oxide and/or other electrically insulating materials. For example, the passivation layer 116 can be a silicon dioxide layer formed by oxidation of the semiconductor substrate 102 (e.g., the silicon wafer). The passivation layer can have a thickness between about 0.1 and 500 μm.

In some embodiments, the TSVs 106 are separated from the semiconductor substrate 102 by the passivation layer 116 and/or another non-conductive layer. In some embodiments, the TSVs 106 and/or 108 are spaced apart from the semiconductor substrate 102 by a layer of non-conductive material (e.g., as described with respect to FIGS. 2F-2G). For example, the sidewalls of the TSVs 106 and/or 108 can be separated from the semiconductor substrate 102 by a layer of dielectric material (e.g., silicon dioxide or silicon nitride) in a direction parallel to the first surface 102a of the semiconductor substrate 102.

The semiconductor device 100 further includes, or is in contact with, contact pads (e.g., contact pads 112). In FIG. 1, each of the TSVs is connected to a pair of contact pads 112 that are located on the exposed ends of the TSVs at the third surface 102c and the second surface 102b. The contact pads 112 are configured for electrically coupling the TSVs to other TSVs to form a three-dimensional interconnect or other electrical elements or devices. The contact pads 112 are made of a conductive material such as copper, aluminum, gold, and/or other suitable conductive materials or alloys thereof.

The semiconductor device 100 including the cavity 110 is configured to receive an additional semiconductor device (e.g., a semiconductor device 104). The semiconductor device 104 includes a top surface 104a and a bottom surface 104b. In FIG. 1 the semiconductor device 104 is positioned within the cavity 110. The semiconductor device 104 can be positioned and sized so that the semiconductor device 104 is co-planar with the first surface 102a of the semiconductor device 104 (e.g., the top surface 104a of the semiconductor device 104 is co-planar with the first surface 102a of the semiconductor device 104). The semiconductor device 104 can have a shape and size that is configured to fully or almost fully occupy the cavity 110. For example, the semiconductor device 104 can have a rectangular cuboid shape that is configured to fit within with a rectangular cuboid shape of the cavity 110.

In some implementations, the semiconductor device 104 is a logic device. A logic device refers to an integrated circuit (IC) element having the primary function of computing and/or processing instructions. The logic device can include a microcontroller, a microprocessor, or an application processor. In some implementations, the logic device is a programmable logic device. A logic device can also include a memory function for supporting and facilitating the primary function of computing and/or processing instructions. Generally, a logic device generates heat as it operates. In order to prevent overheating of a system, the logic device can be thermally coupled to a heat sink. For example, the semiconductor device 104 can be coupled to a thermally conductive heat sink to ensure that heat generated by the semiconductor device 104 is removed from the semiconductor device 100 and/or an assembly or system including the semiconductor device 100.

As shown in FIG. 1, the semiconductor device 104 is electrically coupled with the third surface 102c of the semiconductor substrate 102 via conductive pads 112 and conductive couplers (e.g., conductive couplers 114 such as solder balls). As shown, the conductive couplers 114 extend between the conductive pads 112 to connect the bottom surface 104b of the semiconductor device 104 and the third surface 102c of the semiconductor substrate. The electrical coupling between the semiconductor substrate 102 and the semiconductor device 104 can also be configured, alternatively or additionally, via wire bonds, conductive tapes, and/or other suitable electrical connectors.

Multiple TSVs 106 can be electrically coupled with the semiconductor device 104. As shown in FIG. 1, the three TSVs 106 are coupled with the semiconductor device 104. In some embodiments, the semiconductor device 100 can also more or less than three TSVs (e.g., hundreds of TSVs, tens of TSVs, or even just a single TSV). In other embodiments, the cavity 110 can be configured for receiving two or more semiconductor devices 104. For example, a semiconductor device including two TSVs exposed at the bottom surface of the cavity 110 can be configured to receive two TSVs positioned in the cavity 110 so that each of the TSVs is electrically coupled with a single TSV. As another example, a semiconductor device including two sets of multiple TSVs exposed at the bottom surface of the cavity 110 can be configured to receive two TSVs positioned in the cavity 110 so that each of the TSVs is electrically coupled with a respective TSV.

In some implementations, the semiconductor device 100 includes multiple cavities 110, each of which includes TSVs exposed at a bottom surface thereof. The multiple cavities 110 can be spaced apart from each other by regions of the semiconductor substrate. The multiple cavities 110 can have either the same shape and same size or different shapes and/or different sizes. For example, the multiple cavities 110 can include a first cavity with a first shape and/or size, a second cavity with a second shape and/or size, and a third cavity with a third shape or size where the first, second, and third shapes and/or size are different from each other. Such multiple cavities 110 with different shapes and/or sizes can be configured to receive semiconductor devices 104 of different shapes and/or sizes. The multiple cavities 110 can also be arranged across the first surface 102a in different configurations. For example, four cavities 110 can be arranged across the first surface 102a in a square arrangement, or three cavities 110 can be arranged across the first surface 102a in a linear configuration. In some embodiments, the multiple cavities 110 can be configured to receive different numbers of semiconductor devices 104. For example, the first cavity having the first shape and/or size is configured to receive a single semiconductor device 104 while the second cavity having the second shape and/or size is configured to receive two semiconductor devices 104. The multiple cavities can also be connected to different numbers of TSVs 106. For example, the first cavity having the first shape and/or size includes a first number of TSVs 106 while the second cavity having the second shape and/or size is connected to a second number of TSVs 106 which is different from the first number of TSVs.

FIGS. 2A-2F are simplified schematic cross-sectional views illustrating a series of fabrication steps of forming several embodiments of the semiconductor devices 100 shown in FIG. 1 in accordance with embodiments of the present technology. In the following description, similar processing operations may utilize generally similar processing techniques. As a result, suitable techniques for performing the processing operations (e.g., patterning a deposited material, removing portions of dielectric materials, depositing a conductive material, etc.) are described only once for brevity.

As shown in FIG. 2A, the fabrication can include providing the semiconductor substrate 102 having the second surface 102a and an opposing surface 102e. The semiconductor substrate 102 can be a silicon wafer (e.g., silicon crystal wafer). The second surface 102b of the semiconductor substrate 102 is an active surface and the surface 102e of the semiconductor substrate 102 is a back surface. The active surface can include electric circuits (e.g., patterned integrated circuits) and components (e.g., transistors). The back surface can be modified, for example, for coupling the semiconductor substrate 102 to other components, such as logic devices. The second surface 102b and the surface 102e are flat and perpendicular to each other.

FIGS. 2B-2D illustrate the formation of multiple TSVs within the semiconductor substrate 102. As shown in FIG. 2B, the fabrication includes forming a plurality of apertures (e.g., apertures 202a, 202b, 202c, and 202d collectively called herein as apertures 202). The apertures 202 extend from the second surface 102b through the semiconductor substrate 102 to an intermediate depth (e.g., the apertures 202 extend partially through the semiconductor substrate 102). Forming the apertures 202 can include removing material from the semiconductor substrate by microfabrication methods known in the art such as wet etching, reactive ion etching, or plasma etching. The apertures 202 have longitudinal shapes such that the side walls of the apertures (e.g., sidewalls 202-1) are substantially perpendicular to the second surface 102b and the second surface 102b. The apertures 202 are sized and shaped that they can be used to form the TSVs 106 and 108 described with respect to FIG. 1. The apertures 202 can have uniform heights or varying heights. As shown in FIG. 2B, the aperture 202d has a greater height than the apertures 202a, 202b, and 202c. The apertures 202 can also have uniform diameters or varying diameters. In some embodiments, the apertures 202 have cylindrical shapes (e.g., the apertures are round cylinders or elliptical cylinders). The apertures 202 can be formed in a single process or in two or more separate processes. For example, the set of apertures 202a, 202b, and 202c can be formed in one process and the aperture 202d having a different height and is spaced apart from the set of apertures 202a, 202b, and 202c can be formed in another process.

In some embodiments, the fabrication includes adding one or more layers of non-conductive material on the walls of the apertures 202 (e.g., a non-conductive layer 206 on the walls of the aperture 202d). For example, sidewalls 202-1 of the apertures 202 can include one or more layers of non-conductive materials so that the formed TSVs (e.g., the TSV 108 in FIG. 2D) will be spaced apart from the semiconductor substrate 102 by the non-conductive layer 206 along a direction that is parallel with the second surface 102b. The layer of non-conductive material can include silicon dioxide, silicon nitride, other dielectrics, aluminum oxide and/or other electrically insulating materials. Formation of the non-conductive layer can include thermal oxidation, chemical vapor deposition (CVD), atomic layer deposition (ALD), physical vapor deposition (PVD), spin-on glass, and/or other suitable techniques.

As shown in FIG. 2C, the fabrication includes filling the apertures 202 with a conductive material 204 (e.g., copper, aluminum, gold, and/or other suitable conductive materials or alloys thereof). The filling can include CVD, ALD, PVD, electroplating, and/or other suitable techniques. After filling, the conductive material 204 occupies the whole space of the apertures 202 so that the conductive material extends from the second surface 102b to the full depth of the apertures 202.

As shown in FIG. 2D, the fabrication includes etching the surface 102e to form the first surface 102a of the semiconductor substrate 102 that exposes the top surfaces of the apertures 202 filled with conductive material 204, thereby forming the TSV 108 located in the peripheral regions 102-1 of the semiconductor substrate 102. The formation of second surface 102b can include removing a top portion of the semiconductor substrate 102 by microfabrication methods known in the art such as wet etching, reactive ion etching, or plasma etching.

FIG. 2D also shows the formation of the cavity 110 which is defined by the third surface 102c (e.g., the bottom surface of cavity 110 and fourth surfaces 102d corresponding to the vertical side surfaces of the cavity 110). After formation of the cavity 110, the top surfaces of the apertures 202 filled with the conductive material 204 located within the area below the cavity 110 are exposed thereby forming the TSVs 106. The cavity 110 can be formed using the etching techniques known in the art combined with different types of masking techniques. Masking techniques known in the art can include, for example, a phase-shift mask, leaky-chrome mask, and/or other suitable masking techniques. For example, cavity 110 can be formed by selectively etching the region of the top surface of the semiconductor substrate 102 to remove the portion of the semiconductor substrate 102 corresponding to the cavity 110 while applying a mask on the peripheral regions 102-1 surrounding the cavity 110.

In some embodiments, a portion of the surface 102e is first etched by a first process to remove a top portion of the semiconductor substrate 102 to form a flat top surface after which the cavity 110 is etched using a second process to remove a portion of the substrate corresponding to the region of the cavity 110. In other embodiments, the cavity 110 is first formed by removing the corresponding portion of the semiconductor substrate 102 after which the peripheral regions 102-1 surrounding the cavity are etched to form the second surface 102b. In some embodiments, the peripheral regions 102-1 and the cavity 110 are formed in a single process.

Removal of the top portion of the semiconductor substrate 102 exposes the TSVs 106 at the second surface 102b so that top surfaces 106-1 of the TSVs 106 are exposed. For example, the etching is performed with an etchant that is selective for semiconductor materials of semiconductor substrate 102 (e.g., silicon) and the conductive materials 204 (e.g., copper) so that the top surfaces 106-1 of the TSVs 106 are exposed. In some embodiments, also portions of the conductive materials 204 may be removed so that the exposed TSVs 106 and 108 form flat surfaces that are co-planar with the second surface 102b. For example, in FIG. 2D the second surface 102b is co-planar with a top surface 108-1 of the TSV 108, and the third surface 102c is co-planar with the top surfaces 106-1 of the TSVs 106. In some implementations, the removal of the top portion of the semiconductor substrate 102 and removal of the top portions of the conductive materials 204 are done in a single process (e.g., a single etching process). In some implementations, the removal of the top portion of the semiconductor substrate 102 and removal of the top portions of the conductive materials 204 are done in two different processes. For example, the top portion of the semiconductor substrate 102 is removed by a first process so that top portions of the conductive material are protruding from the second surface 102b. The protruding top portions of the conductive material 204 are then removed by a second process so that the top surfaces of the TSVs are co-planar with the second surface 102b. In some embodiments, the top surfaces 106-1 and 108-1 of the TSVs 106 and 108 are not co-planar with the respective surfaces 102b and 102c. Instead, the top surfaces 106-1 and 108-1 of the TSVs 106 and/or 108 can protrude from the respective surfaces 102b and 102c.

As shown in FIG. 2E, the fabrication can include forming the passivation layer 116 that extends at least partially across the second surface 102b, the third surface 102c, and/or the side surfaces 102d of the cavity 110. In FIG. 2E, the passivation layer 116 extends across the second surface 102b, the third surface 102c, and the side surfaces 102d so that the TSVs 106 and 108 are exposed. In FIG. 1, the passivation layer 116 was illustrated to extend only over the third surface 102c and the side surfaces 102d. As described above with respect to FIG. 1, the passivation layer 116 can include silicon dioxide, silicon nitride, other dielectrics, aluminum oxide and/or other electrically insulating materials. Formation of the passivation layer 116 can include thermal oxidation, CVD, PVD, ALD, spin-on glass, and/or other suitable techniques. For example, the formation of the passivation layer 116 includes thermal oxidation of the semiconductor substrate 102 (e.g., a silicon wafer) which leaves the conductive top surfaces of the TSVs exposed. As another example, the formation of the passivation layer 116 includes deposition of a non-conductive material by a CVD, PVD, or ALD technique on the semiconductor substrate 102. The top surfaces of the TSVs 106 and 108 can be left exposed by applying a mask on the top surfaces of the TSVs during the deposition or alternatively by removing the non-conductive material from the top surfaces of the TSVs after the deposition.

As shown in FIG. 2F, the fabrication can include forming the contact pads 112. As shown in FIG. 2F, multiple contact pads 112 have been formed so that each of the TSVs 106 is connected to a pair of contact pads 112 that are connected to the exposed surfaces of the TSVs at the third surface 102c and the second surface 102b. For example, each contact pad 112 is formed directly upon a respective TSV 106 or 108. The contact pads 112 are made of a conductive material (e.g., copper, aluminum, gold, and/or other suitable conductive materials or alloys thereof). Forming the contact pads 112 depositing the conductive material selectively on the regions corresponding to exposed TSVs 106 and 108 using metal deposition techniques known in the art (e.g., PVD, CVD, ALD, electroplating, and/or other suitable techniques together with suitable masking techniques). Alternatively or additionally, the fabrication can include the addition of electrical connectors including wire bonds, conductive tapes, and/or other suitable electrical connectors

As shown in FIG. 2G, the fabrication can include positioning the semiconducting device 104 into the cavity 110 and forming electrical connections between the semiconducting device 104 and the TSVs 106. As shown, the semiconducting device 104 is positioned in the cavity 110 so that the surface 104b of the semiconducting device 104 is co-planar with the second surface 102b. The cavity 110 and the semiconductor device 104 can be sized so that the semiconductor device 104 is separated from the side surfaces 102d of the cavity 110 by a distance (e.g., by the passivation layer 116, and optionally by a gap). The surface 104a of the semiconductor device 104 can be electrically coupled with the third surface 102c via a pair of contact pads 112 and conductive couplers 114 such as solder balls. As shown, top surfaces 106-1 of each of the TSV 106 are in contact with a respective contact pad 112. The surface 104a of the semiconductor device 104 further includes contact pads 112 positioned so that each of the contact pads 112 can be paired with a respective contact pad 112 in contact with the TSVs 106. The pairs of contact pads 112 are electrically coupled to each other by the conductive couplers 114 sandwiched between the contact pads 112.

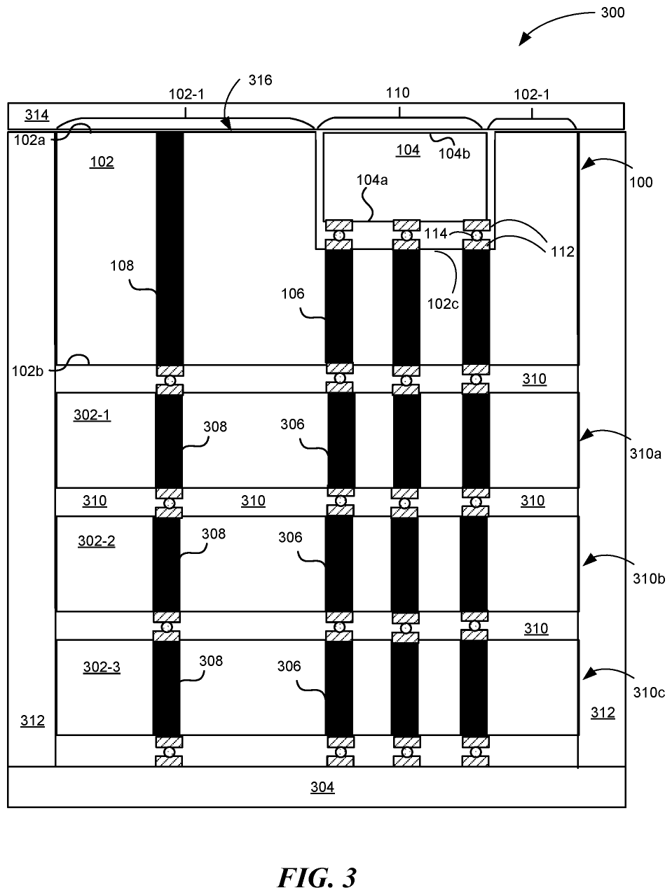

FIG. 3 is a simplified schematic cross-sectional view of a semiconductor device assembly 300 in accordance with embodiments of the present technology. The assembly 300 includes a package substrate 304 (e.g., a printed circuit board (PCB)) and a stack of semiconductor devices (e.g., semiconductor devices 302a, 302b, and 302c collectively referred to as semiconductor devices 302). The semiconductor devices 302 can be, for example, memory devices. The semiconductor devices 302 are arranged in a vertical stack so that the semiconductor devices 302 are positioned on top of each other. The stack of semiconductor devices 302 is positioned on top of the package substrate 304. The semiconductor devices 302 include a plurality of TSVs 306 corresponding to the TSVs 106 described with respect to FIG. 1. As shown, the TSVs 306 are vertically aligned so that each of the TSVs is electrically coupled with at least one TSV of another semiconductor device 302 thereby forming vertical electrical interconnects. The electrical coupling is configured via pairs of contact pads 112 and electrical couplers 114 positioned between the contact pads 112, as described with respect to FIG. 1 The semiconductor devices 302 can also include one or more additional TSVs 308 corresponding to TSVs 108 described with respect to FIG. 1. For example, the TSVs 308 and 108 are thermally conducting TSVs. The TSVs 106 and 108 of the lowest semiconductor device 302-3 of the stack of semiconductor devices 302 are electrically coupled with a top surface of the package substrate 304.

The assembly 300 also includes the semiconductor device 100 described with respect to FIGS. 1-2G. It is noted that the semiconductor device 100 includes a thicker semiconductor substrate 102 compared to the semiconductor substrates of the semiconductor devices 302 (e.g., the semiconductor device 100 has a greater height than the semiconductor devices 302). The semiconductor device 100 of the assembly 300 (e.g., also referred to as a top semiconductor device) is positioned on top of the stack of the semiconductor devices 302. As described above, the semiconductor device 100 includes the semiconductor substrate 102 including the cavity 110 and the peripheral region 102-1. The peripheral region 102-1 includes the first surface 102a and the second surface 102b which is opposite to the first surface 102a. The cavity 110 extends from the first surface 102a partially through the semiconductor substrate 102 to the third surface 102c. The semiconductor device 100 also includes the TSVs 106 that extend between the third surface 102c and the first surface 102a. The assembly 300 also includes the semiconductor device 104 which is positioned in the cavity 110 and is electrically coupled with the TSVs 106 of the semiconductor device 100.

The assembly 300 further includes a thermally conductive heat sink 314. The heat sink 314 is made of a material having high heat capacity and thermal conductivity for purpose of absorbing heat generated by the assembly 300 (e.g., the semiconductor device 104) and releasing it to the environment. The heat sink 314 can be made, for example, of aluminum alloy. As shown, the heat sink 314 is coupled with the first surface 102a of the semiconductor device 100 and the top surface 104b of the semiconductor device 104. As shown, the surfaces 102a and 104b are co-planar and parallel with the bottom surface of the heat sink 314. In some embodiments, the assembly further includes a thermally conductive adhesive 316 (e.g., thermally conductive tape) positioned between the co-planar surfaces 102a and 104b and the heat sink 314. The thermally conductive adhesive 316 is configured to adhesively couple the surfaces 102a and 104b to the bottom surface of the heat sink 314.

As shown in FIG. 3, the cavity 110 of the semiconductor device 100 provides for a convenient location for positioning an additional semiconductor device (e.g., the semiconductor device 104), such as a logic device. For example, the semiconductor device 104 is a logic device configured to manage the semiconductor devices 302 (e.g., memory devices) arranged in the stack.

The semiconductor device 104 can be positioned near the heat sink 314 without the need for conducting the heat generated by the semiconductor device 104 through the assembly 300 to the heat sink 314. The cavity 110 also allows the semiconductor device 104 to be pocketed within the assembly for compact packaging of the assembly 300 (e.g., instead of being positioned outside the assembly 300).

The assembly 300 can further include an encapsulating material 312 that at least partially encapsulates the semiconductor devices 302 and the semiconductor device 100 stacked together. The encapsulating material 312 is configured to protect the semiconductor devices 301 and 100 from damage and/or environmental factors such as corrosion. The encapsulating material 312 can include, for example, epoxy or silica. The assembly 300 can further include filler material 310 (e.g., resin) configured to protect the semiconductor devices 302 and the semiconductor device 100 stacked together. The filler material 310 can, for example, occupy the space between the different semiconductor devices in the assembly 300.

As described above with respect to FIG. 1, the semiconductor device 100 can include multiple cavities 110. Also, a single cavity 110 can be configured to receive multiple semiconductor devices 104. The assembly 300 can therefore include multiple semiconductor devices 104 positioned in the multiple cavities so that the multiple semiconductor devices 104 are electrically coupled with the heat sink 314 (e.g., by the thermally conductive adhesive 316).

Although in the foregoing example embodiment semiconductor devices and semiconductor device assemblies have been illustrated and described as including a single semiconductor device, in other embodiments assemblies can be provided with additional semiconductor devices. For example, the single semiconductor devices illustrated in FIG. 1 could be replaced with, e.g., a vertical stack of semiconductor devices, a plurality of semiconductor devices, mutatis mutandis.

Although in the foregoing example embodiment semiconductor devices and semiconductor device assemblies have been illustrated and described as including TSVs extending into a back-side cavity and formed from the front side of the semiconductor device before the cavity is etched, in other embodiments assemblies can be provided with cavities etched in the back surface and TSVs formed from the back side (e.g., plating from the back side into openings formed from either the back of front side) of the semiconductor device.

In accordance with one aspect of the present disclosure, the semiconductor devices and assemblies illustrated in the FIGS. 1-3 could be memory dies, such as dynamic random access memory (DRAM) dies, NOT-AND (NAND) memory dies, NOT-OR (NOR) memory dies, magnetic random access memory (MRAM) dies, phase change memory (PCM) dies, ferroelectric random access memory (FeRAM) dies, static random access memory (SRAM) dies, or the like. In an embodiment in which multiple dies are provided in a single assembly, the semiconductor devices could be memory dies of a same kind (e.g., both NAND, both DRAM, etc.) or memory dies of different kinds (e.g., one DRAM and one NAND, etc.). In accordance with another aspect of the present disclosure, the semiconductor dies of the assemblies illustrated and described above could be logic dies (e.g., controller dies, processor dies, etc.), or a mix of logic and memory dies (e.g., a memory controller die and a memory die controlled thereby).

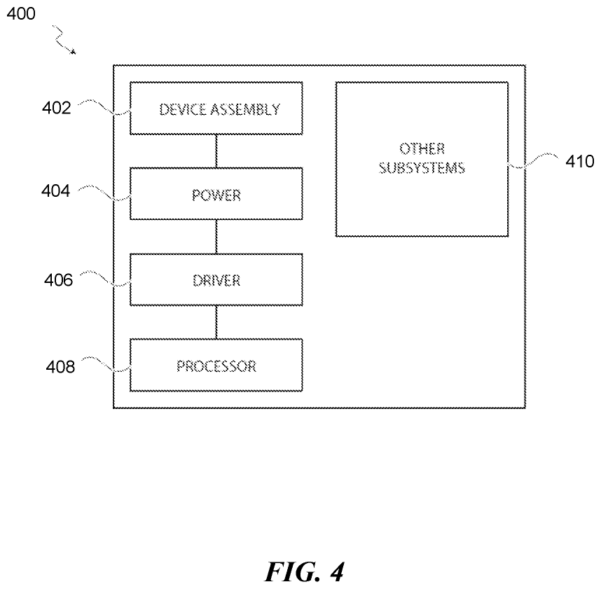

Any one of the semiconductor devices and semiconductor device assemblies described above with reference to FIGS. 1-3 can be incorporated into any of a myriad of larger and/or more complex systems, a representative example of which is a system shown schematically in FIG. 4.

FIG. 4 is a schematic view showing a system 400 that includes a semiconductor device assembly configured in accordance with an embodiment of the present technology. The system 400 can include a semiconductor device assembly (e.g., or a discrete semiconductor device) 402, a power source 404, a driver 406, a processor 408, and/or other subsystems or components 410. The semiconductor device assembly 402 can include features generally similar to those of the semiconductor devices described above with reference to FIGS. 1-3. The resulting system 400 can perform any of a wide variety of functions, such as memory storage, data processing, and/or other suitable functions. Accordingly, representative systems 400 can include, without limitation, hand-held devices (e.g., mobile phones, tablets, digital readers, and digital audio players), computers, vehicles, appliances, and other products. Components of the system 400 may be housed in a single unit or distributed over multiple, interconnected units (e.g., through a communications network). The components of the system 400 can also include remote devices and any of a wide variety of computer-readable media.

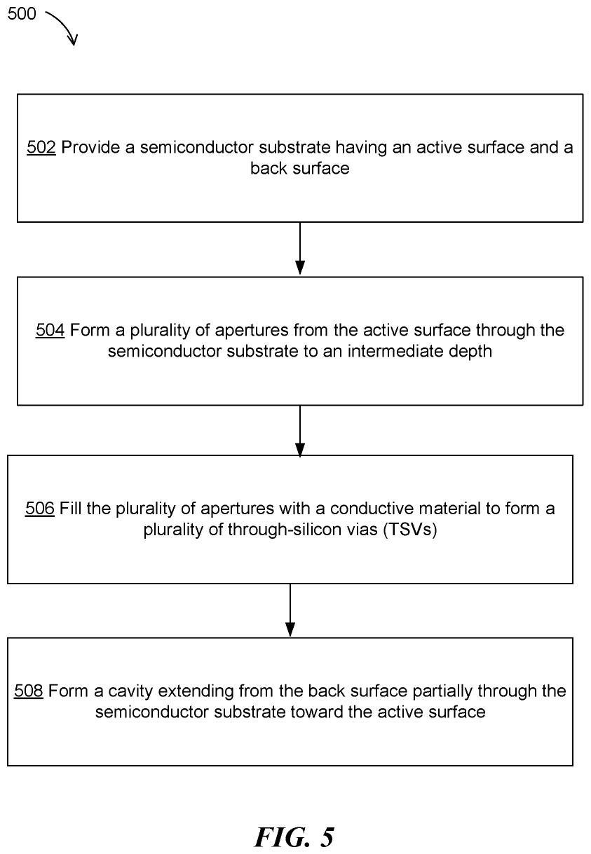

FIG. 5 is a flow chart illustrating a method of making a semiconductor device assembly in accordance with an embodiment of the present technology. The method 500 includes providing a semiconductor substrate having an active surface and a back surface (box 502). The method 500 further includes forming a plurality of apertures extending from the active surface partially through the semiconductor substrate to an intermediate depth (box 504). The method 500 further includes filling the plurality of apertures with a conductive material to form a plurality of through-silicon vias (TSVs) (box 506). In some embodiments, the method 500 includes forming a conformal layer of non-conductive material over the plurality of apertures so that each of the plurality of TSVs is spaced apart from the semiconductor substrate. The method 500 also includes forming a cavity that extends from the back surface partially through the semiconductor substrate toward the active surface (box 508). In some embodiments, the method 500 includes forming a passivation layer over the back surface, the bottom surface of the cavity, and side-walls of the cavity The cavity includes a bottom surface that is parallel to a peripheral region of the back surface. The plurality of TSVs are exposed at the bottom surface. In some embodiments, the method further includes forming a plurality of contact pads so that a respective contact pad of the plurality of contact pads is in contact with a respective TSV of the plurality of TSVs.

Specific details of several embodiments of semiconductor devices, and associated systems and methods, are described above. A person skilled in the relevant art will recognize that suitable stages of the methods described herein can be performed at the wafer level or at the die level. Therefore, depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques.

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “vertical,” “lateral,” “upper,” “lower,” “above,” and “below” can refer to relative directions or positions of features in the semiconductor devices in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

It should be noted that the methods described above describe possible implementations, and that the operations and the steps may be rearranged or otherwise modified and that other implementations are possible. Furthermore, embodiments from two or more of the methods may be combined.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A semiconductor device, comprising:
a semiconductor substrate including a cavity and a peripheral region surrounding the cavity, wherein:
the peripheral region includes a first surface and a second surface opposite the first surface,
the cavity extends from the first surface partially through the semiconductor substrate to a third surface between the first surface and the second surface, the third surface being parallel to the first surface; and
a plurality of through-silicon vias (TSVs) extending between the first surface and the third surface.

2. The semiconductor device of claim 1, wherein:
the cavity is configured to receive an additional semiconductor device electrically coupled with the plurality of TSVs at the third surface.

3. The semiconductor device of claim 1, further comprising:
a passivation layer extending across the first surface, the third surface, and side-walls of the cavity.

4. The semiconductor device of claim 1, wherein:
the plurality of TSVs are exposed at the third surface.

5. The semiconductor device of claim 4, further comprising:
a plurality of contact pads, wherein each contact pad of the plurality of contact pads is formed directly upon a respective TSV of the plurality of TSVs.

6. The semiconductor device of claim 1, wherein:
each of the plurality of TSVs is spaced apart from the semiconductor substrate by a layer of non-conductive material.

7. A semiconductor device assembly, comprising:
a package substrate;
a stack of a semiconductor devices coupled with the package substrate, each including a plurality of through silicon vias (TSVs);
a top semiconductor device of the stack including:
a semiconductor substrate including a cavity and a peripheral region surrounding the cavity, wherein:
the peripheral region includes a first surface and a second surface opposite the first surface,
the cavity extends from the first surface partially through the semiconductor substrate to a third surface between the first surface and the second surface, the third surface being parallel to the first surface; and
a plurality of TSVs of the top semiconductor device extending between the first surface and the third surface.

8. The semiconductor device assembly of claim 7, wherein:
the plurality of TSVs of the top semiconductor device are exposed at the third surface.

9. The semiconductor device assembly of claim 7, further comprising:
an additional semiconductor device positioned within the cavity of the semiconductor substrate and electrically coupled to the plurality of TSVs at the third surface.

10. The semiconductor device assembly of claim 9, wherein a top surface of the additional semiconductor device and the first surface are co-planar.

11. The semiconductor device assembly of claim 9, wherein:
the additional semiconductor device is a logic device, and the stack of semiconductor devices includes a plurality of memory devices managed by the logic device.

12. The semiconductor device assembly of claim 9, further comprising:
a first plurality of contact pads of the top semiconductor device, wherein a respective conductivity pad of the first plurality of contact pads is coupled to a respective TSV of the plurality of TSVs;
a second plurality of contact pads of the additional semiconductor device, wherein the additional semiconductor device is electrically coupled with the plurality of TSVs by electrically coupling the first plurality of contact pads and the second plurality of contact pads.

13. The semiconductor device assembly of claim 10, further comprising:
a thermally conductive heat sink coupled with the first surface of the top semiconductor device and the top surface of the additional semiconductor device.

14. The semiconductor device assembly of claim 7, further comprising:
an encapsulating material at least partially encapsulating the stack of semiconductor devices.

15. The semiconductor device assembly of claim 7, further comprising:
a passivation layer extending across the first surface, the third surface, and side-walls of the cavity region of the top semiconductor device.

16. The semiconductor device assembly of claim 7, wherein:
each of the plurality of TSVs is separated from the semiconductor substrate, along a direction that is parallel to the first surface, by a corresponding layer of non-conductive material.

17. A method of making a semiconductor device, comprising:
providing a semiconductor substrate having an active surface and a back surface;
forming a plurality of apertures extending from the active surface partially through the semiconductor substrate to an intermediate depth;
filling the plurality of apertures with a conductive material to form a plurality of through-silicon vias (TSVs); and
forming a cavity that extends from the back surface partially through the semiconductor substrate toward the active surface, wherein:
the cavity includes a bottom surface that is parallel to a peripheral region of the back surface, and
the plurality of TSVs are exposed at the bottom surface.

18. The method of claim 17, further comprising:
forming a passivation layer over the back surface, the bottom surface of the cavity, and side-walls of the cavity.

19. The method of claim 17, further comprising:
forming a plurality of contact pads so that a respective conductivity pad of the plurality of contact pads is in contact with a respective TSV of the plurality of TSVs.

20. The method of claim 17, further comprising:
forming a conformal layer of non-conductive material in each of the plurality of apertures so that each of the plurality of TSVs is spaced apart from the semiconductor substrate.
